(19) United States
(12) Patent Application Publication
(10) Pub. No.: US 2022/0029384 A1
(43) Pub. Date: Jan. 27, 2022

(54) TUNABLE DUAL AND MULTIPLE WAVELENGTH LASER SYSTEM

(71) Applicants: KING ABDULLAH UNIVERSITY OF SCIENCE AND TECHNOLOGY, Thuwal (SA); KING FAHD UNIVERSITY OF PETROLEUM AND MINERALS, Dhahran (SA)

(72) Inventors: Mohammed Zahed Mustafa KHAN, Dhahran (SA); Md Hosne Mobarok SHAMIM, Montreal (CA); Tien Khee NG, Thuwal (SA); Boon Siew OOI, Thuwal (SA)

(21) Appl. No.: 17/281,705

(22) PCT Filed: Sep. 25, 2019
(86) PCT No.: PCT/IB2019/058140

§ 371 Date: Mar. 31, 2021

Related U.S. Application Data
(60) Provisional application No. 62/740,009, filed on Oct. 2, 2018.

(51) Int. Cl. H01S 5/10; G02F 1/35; H01S 5/343; H01S 5/00

(52) U.S. Cl. CPC H01S 5/1096; G02F 1/353; G02F 2203/13; H01S 5/34333; H01S 5/0092; H01S 5/1039

(57) ABSTRACT

A tunable laser system includes a laser diode producing a light beam having a plurality of frequencies in a visible portion of a light spectrum. A collimating lens arranged in front of the laser diode produces a collimated light beam from the light beam produced by the laser diode. A partial reflector arranged in a path of the collimated laser beam reflects a first portion of the collimated light beam and passes a second portion of the collimated light beam as an output light beam. The first portion of the collimated light beam enters the laser diode and mixes with the plurality of frequencies of the light beam produced by the laser diode so that the laser diode produces a self-injection-locked light beam including at least two frequencies having a frequency difference in a terahertz frequency range. A translational stage adjusts a distance between the laser diode and the partial reflector. The laser diode or the partial reflector is mounted on the translational stage. The at least two frequencies of the self-injection-locked light beam are based on the distance between the laser diode and the partial reflector.

### CROSS-REFERENCE TO RELATED APPLICATIONS

This application claims priority to U.S. Provisional Patent Application No. 62/740,009, filed on Oct. 2, 2018, entitled “TERAHERTZ PHOTONIC SIGNAL GENERATION USING SELF-INJECTION LOCKED VISIBLE LASER DIODE,” the disclosure of which is incorporated herein by reference in its entirety.

### BACKGROUND

### Technical Field

Embodiments of the disclosed subject matter generally relate to a laser system that can produce dual or multiple wavelength light beams having a tunable frequency difference in the range of terahertz frequencies.

### Discussion of the Background

Signals exhibiting terahertz frequencies (i.e., frequencies ranging between 0.1 THz-10 THz) have a spatial resolution of less than a millimeter, and accordingly such signals have shown promise in a number of fields, such as imaging and sensing. For example, molecules of various materials are sensitive at terahertz frequencies, which could potentially be exploited for sensing in the bio-photonics and chemical industries. Other emerging applications of terahertz frequencies include, but are not limited to, broadband indoor wireless communication, advanced radar systems, high speed signal processing, environmental monitoring, remote sensing, etc. Attempts to generate terahertz frequencies using electronic systems have met with limited success due to the speed limitations on the electronic systems.

Photonic generation, i.e., using lasers, has been investigated as an alternative to electronic systems for generating terahertz frequencies. One solution is using an optical coupler to perform heterodyne mixing of two laser inputs to generate microwave to sub-millimeter photonic signals. This solution typically employed two single mode semiconductor slave lasers that are externally-injection-locked by a multimode wideband mode-locked master laser at two different wavelengths in the millimeter/sub-millimeter region. The outputs of these lasers are then combined in an optical coupler to produce the millimeter or microwave photonic signal of the desired frequency. This solution requires coherency of the two lasers, which is non-trivial, thus the laser produced by such systems typically exhibit considerable phase noise. System reliability is also an issue because performance drops proportionally with the laser misalignment, and often, loss of lasers coherency.

As an alternative to the use of two lasers, a single vertical cavity surface emitting laser (VCSEL) with an intrinsically broadened gain has been employed to generate two wavelengths simultaneously in order to generate terahertz frequencies. In this solution a pump source is utilized to obtain stimulated emission in VCSEL using an external cavity configuration. A wavelength selective filter was disposed in the external cavity to select any two modes, which were ˜2 nm apart from each other and operated at around 970 nm. In another solution, two VCSELs were used at the same wavelengths to generate terahertz signals using the difference frequency generation (DFG). Another solution involved distributed feedback (DFB) lasers operated at 1550 nm and 1538 nm to produce terahertz signals. However, this method increases the noise of the generated terahertz signal. Moreover, operating at higher frequencies or longer wavelengths limits, to some extent, the ability to produce higher terahertz frequencies, in range of few terahertz. Besides, DFB and VCSEL are not commercially available in the visible wavelengths.

Thus, there is a need for an improved system that is tunable to produce a wide range of terahertz frequencies without involving the cost and complexity of a commonly employed two laser system.

### SUMMARY

According to an embodiment, there is a tunable laser system for photonic generation of the terahertz frequencies, which includes a laser diode configured to produce a light beam having a plurality of frequencies in a visible portion of a light spectrum. A collimating lens is arranged in front of the laser diode and is configured to produce a collimated light beam from the light beam produced by the laser diode. A partial reflector is arranged in a path of the collimated laser beam and configured to reflect a first portion of the collimated light beam and to pass a second portion of the collimated light beam as an output light beam. The first portion of the collimated light beam enters the laser diode and mixes with the plurality of frequencies of the light beam produced by the laser diode so that the laser diode produces a self-injection-locked light beam including at least two frequencies that have a frequency difference in a terahertz frequency range. A translational stage is configured to adjust a distance between the laser diode and the partial reflector. The laser diode or the partial reflector is mounted on the translational stage. The at least two frequencies of the self-injection-locked light beam are based on the distance between the laser diode and the partial reflector.

According to another embodiment, there is method of using a tunable laser system. A laser diode outputs a light beam comprising a plurality of frequencies within a visible portion of a light spectrum. The light beam is passed through a collimating lens to produce a collimated light beam. The collimated light beam is provided to a partial reflector. A first portion of the collimated light beam reflects back into the laser diode and a second portion of the collimated light beam passes through the partial reflector. The laser diode outputs, due to mixing of the light beam and the first portion of the collimated light beam, a self-injection-locked light beam comprising at least two frequencies in the visible portion of the light spectrum and having a frequency difference in a terahertz frequency range. A distance between the laser diode and the partial reflector is adjusted to select the at least two frequencies of the self-injection-locked light beam.

According to a further embodiment, there is a method producing a dual wavelength tunable laser system. A laser diode, partial reflector, collimating lens, and translational stage are provided. The laser diode is configured to produce a light beam having a plurality of frequencies in a visible portion of a light spectrum. The laser diode, partial reflector, and collimating lens are arranged so that a laser output from the laser diode passes through the collimating lens to the partial reflector. The laser diode or the partial reflector is arranged on the translational stage. A distance between the laser diode and partial reflector is adjusted, by moving the translational stage, so that a light beam reflected by the partial reflector into the laser diode mixes with a light beam produced by the laser diode to produce a self-injection-locked light beam comprising at least two frequencies in the visible portion of the light spectrum and having a frequency difference in a terahertz frequency range. The at least two frequencies of the self-injection-locked light beam are based on the distance between the laser diode and the partial reflector.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIGS. 1A and 1B are schematic diagrams of a tunable dual and multiple wavelength laser systems according to embodiments;

FIGS. 2A-2C are graphs of wavelengths produced by a tunable dual and multiple wavelength laser system according to embodiments;

FIG. 3 is a schematic diagram of a laser diode according to embodiments;

FIG. 4 is a flow diagram of a method for tuning the at least two wavelengths of the light beam output of a laser according to embodiments; and

FIG. 5 is a flow diagram of a method of producing a tunable laser system according to embodiments.

### DETAILED DESCRIPTION

The following description of the exemplary embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to the terminology and structure of a tunable laser system.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

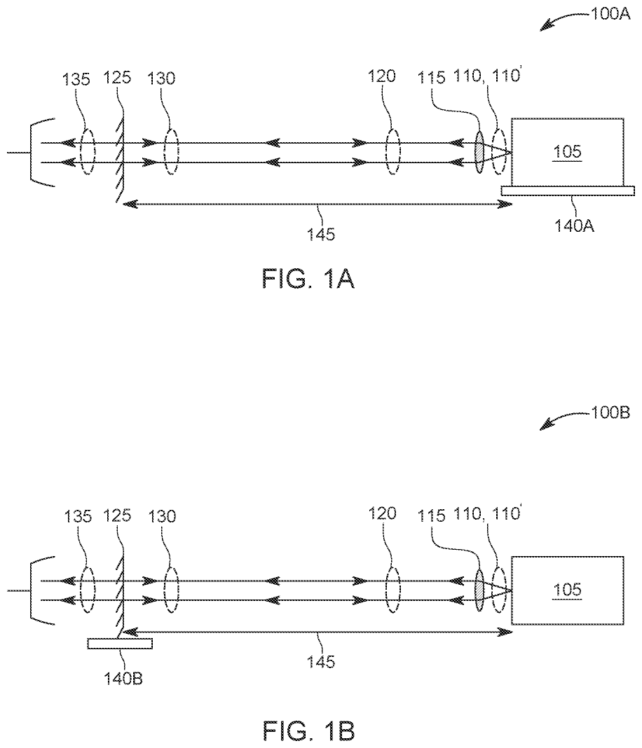

FIGS. 1A and 1B are schematic diagrams of tunable laser systems according to embodiments. The tunable laser systems 100A and 100B include a laser diode 105 configured to produce a light beam 110 having a plurality of frequencies in a visible portion of the light spectrum. A collimating lens 115 is arranged in front of the laser diode 105 and configured to produce a collimated beam 120 from the divergent light beam 110 produced by the laser diode 105. A partial reflector 125 is arranged in a path of the collimated light beam 120 and is configured to reflect a first portion 130 of the collimated light beam 120 and to pass a second portion 135 of the collimated beam 120 as an output light beam. The first portion 130 of the collimated light beam 120 enters the laser diode 105 and mixes with the plurality of frequencies of the light beam 110 produced by the laser diode 105 so that the laser diode 105 produces a self-injection-locked light beam 110′ comprising at least two frequencies that have a frequency difference in a terahertz frequency range. The system also includes a translational stage 140A or 140B configured to adjust the distance 145 between the laser diode 105 and the partial reflector 125. The laser diode 105 (FIG. 1A) or the partial reflector 125 (FIG. 1B) is mounted on the translational stage 140A or 140B. The at least two frequencies of the self-injection-locked light beam 110′ are based on the distance 145 between the laser diode 105 and the partial reflector 125. It should be recognized that when the laser diode 105 is mounted on the translational stage 140A, the collimating lens 115 can also be mounted on the translational stage 140A so as to maintain a fixed distance between the laser diode 105 and the collimating lens 115. If the laser diode 105 is a dual wavelength laser diode, the at least two frequencies of the self-injection-locked light beam 110′ include only two frequencies and if the laser diode is a multiple wavelength laser diode, the at least two frequencies include more than two frequencies. In both cases, the frequency difference between the two or more than two frequencies will be in the terahertz frequency range.

As will be appreciated, in the systems of FIGS. 1A and 1B, the laser diode 105 is self-injection-locked by mixing, inside of the laser diode 105, the light beam 110 of the laser diode 105 with the first portion 130 of the collimated light beam 120 so that the self-injection-locked light beam 110′ includes the at least two frequencies in the visible light range that have a frequency difference in the terahertz frequency range, which is a frequency in the range of 0.1 THz-10 THz. Specifically, the reflected portion 130 of the laser enters the laser diode 105 where it mixes with all the plurality of frequencies produced by the light beam 110 but resonates with only the at least two laser frequencies (only two laser frequencies in the case of a dual wavelength laser diode and more than two laser frequencies in the case of a multiple wavelength laser diode) that exhibit constructive interference due to tuning of the distance 145 between the laser diode 105 and the partial reflector 125, and hence gets injection-locked. This phenomenon is commonly known as self-injection-locking of the two laser wavelengths (or self-injection-locking of the laser diode 105). This light beam produced within the laser diode 105 and the locked light beam 110′ exiting out of the laser diode 105 now exhibits at least two self-injection-locked wavelengths or frequencies with frequency in the terahertz range. Those skilled in the art will recognize that laser diodes that produce different frequencies within its emission are structurally different, i.e., a laser diode that produces a laser emission in the visible spectrum is physically different from a laser diode that produces a laser emission in the infrared spectrum.

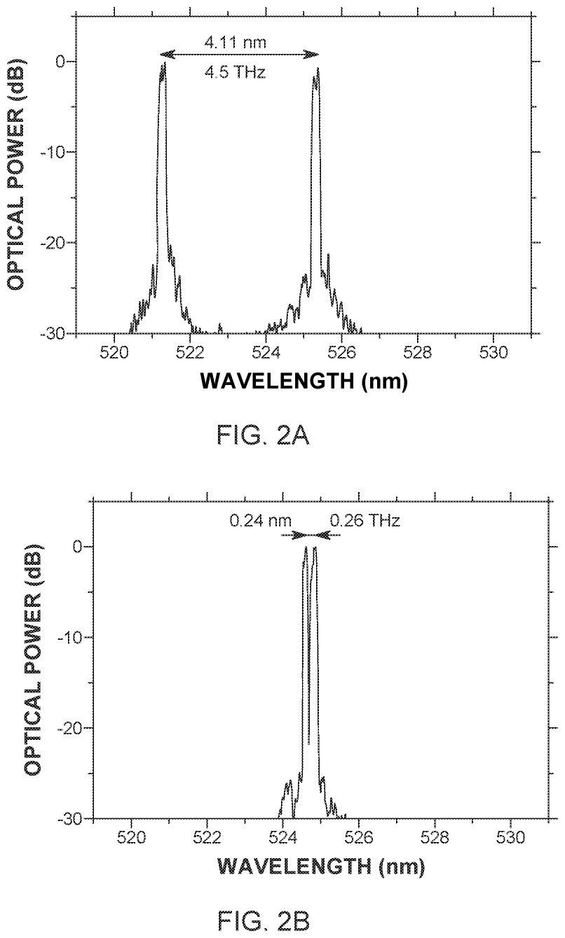

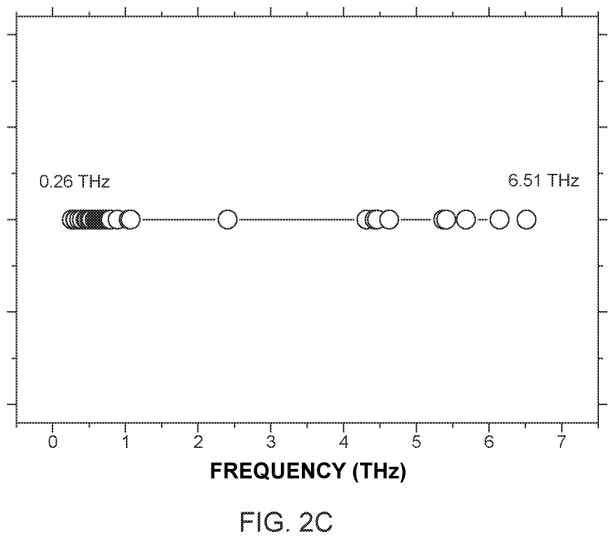

An example of the range of terahertz frequencies that can be achieved using the disclosed tunable laser system is illustrated in the graphs of FIGS. 2A-2C. The laser diode used to generate these frequencies included an indium gallium nitride/gallium nitride (InGaN/GaN) active region of multiple quantum wells. It will be recognized that other types of laser diodes that produce lasers having frequencies in the visible spectrum can be employed, including a III-nitride active region (e.g., Ill-nitride multiple quantum wells or III-nitride quantum dot layers (i.e., alternating InGaN and GaN quantum dot layers), gain chips, etc.

FIG. 2A illustrates the two wavelengths (also referred to as longitudinal wavelength modes) or two frequencies that are the output from the laser diode 105 due to the self-injection locking of the light beam produced by the laser diode 105 with the reflected beam. As illustrated, the two wavelengths have peaks at approximately 521.5 nm and 525.5 nm, which are in the visible spectrum, and thus the self-injection-locked light beam 110′ output from the laser diode 105 has a frequency difference of 4.5 THz, which corresponds to 4.11 nm wavelength difference between the two wavelength modes and commonly known as beat frequency. This frequency was obtained at a distance 145 of 26 cm ±xx μm between the laser diode 105 and partial reflector 125. Similarly, as illustrated in FIG. 2B, a distance 145 of 26 cm ±yy μm between the laser diode 105 and partial reflector 125. Hence, a beat frequency or a frequency difference of 0.26 THz, which corresponds to wavelength difference of 0.24 nm between the two wavelength modes or two frequencies of the self-injection-locked light beam 110′, can be achieved. The terms xx and yy are values in the sub-micrometer to few micrometer range such that the phase of the at least two frequencies of the light beam 110 of the laser diode 105 equals the phase of the two times the distance 145, to achieve the desired at least two frequencies in the self-injection-locked light beam 110′. In the evaluation, the smallest distance was 5 cm and the largest distance was 50 cm, which suggests a great flexibility while designing the distance 145 between the laser diode 105 and the partial reflector 125. The distance 145 can be set based on the desired wavelengths or the frequencies of the two modes (in general A) using the following equation:

$$L = \frac{N λ}{2 {n}_{eff}} \qquad ( 1 )$$

where L is the distance between the laser diode 105 and partial reflector 125, n_{eff} is the effective index of refraction of the medium between the laser diode 105 and partial reflector 125 (which is 1 in the disclosed embodiment because the system employs an open-air cavity), and N is the wavelength mode number which is an integer. Therefore, the distance, L of the external cavity 145 must be an integer multiple of the half of the desired wavelength.

As will be appreciated from the graphs illustrated in FIGS. 2A and 2B, the longitudinal wavelength modes of the self-injection-locked light beam 110′ exhibit at least a 5 dB side mode suppression ratio, thus providing a high quality laser beam.

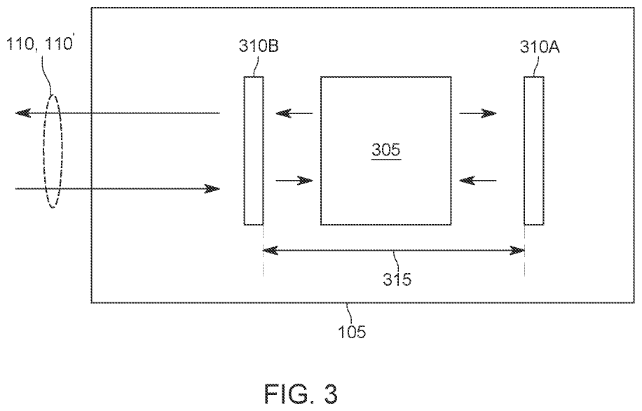

The graphs illustrated in FIGS. 2A and 2B show the possible wavelengths achievable by the disclosed tunable laser system 100A or 110B and it will be recognized that other wavelengths can be achieved using different distances 145 between the laser diode 105 and the partial reflector 125 and/or by adjusting the operational parameters of the laser diode 105 (as discussed below in connection with FIG. 3). As illustrated in FIG. 2C, the disclosed tunable laser system 100A or 100B was able to achieve a terahertz frequency range between 0.26 THz and 6.51 THz, which encompasses almost the complete terahertz frequency range (i.e., 0.1 THz-10 THz). Tunability within such a large frequency range within the terahertz frequencies is particularly advantageous because it allows the disclosed system to be used in a wide variety of applications that may require significantly different frequencies within the terahertz frequency range.

Returning again to FIGS. 1A and 1B, the system exhibits an external cavity configuration in which the cavity is the open-air space between the laser diode 105 and the partial reflector 125. The partial reflector 125 can exhibit any amount of reflectivity as desired, although in a typical implementation the partial reflector 125 can exhibit a reflectivity of greater than ˜10%, and accordingly the partial reflector can exhibit a reflectivity in the range of, for example, 10%-99%. The disclosed tunable laser system can achieve an injection ratio, i.e., the ratio of the optical feedback power (the power fed back to the laser diode 105 from the partial reflector 125) to the optical power produced by the laser diode 105 and measured from the output light beam 110 when no reflected power enters the laser diode 105, in the range of −50 dB to −1 dB. The translational stage 140A or 140B can be a manually operated translational stage or can be motorized.

The embodiments illustrated in FIGS. 1A and 1B involve the laser diode 105, partial reflector 125, and collimating lens 115 being arranged along a single optical axis, which reduces the complexity of the system. However, it should be recognized that these elements can be arranged along more than one optical axis if desired.

In addition to tuning based on the distance between the laser diode 105 and the partial reflector 125, the laser diode 105 itself can be tunable based on operational parameters. For example, the at least two wavelengths of the self-injection-locked light beam generated by the laser diode 105 can be tunable based on injection current to the laser diode 105 and/or based on the temperature of the laser diode 105 (e.g., by heating or cooling the laser diode 105). Referring now to FIG. 3, which illustrates a typical configuration of a laser diode, the light beam generated by the semiconductor gain medium 305 of the laser diode 105 resonates between two partial mirrors 310A and 310B in order to produce a light beam 110 or 110′ that is output from the laser diode 105. Accordingly, the distance 315 between the two partial mirrors 310A and 310B forms the internal laser cavity, and the distance 145, which is the distance between the partial mirror 125 and the laser diode 105 internal partial mirror 310B, is the actual external cavity of the tunable laser system. The distance 315 can be, for example between 300 and 1500 μm. Further, this distance 315 can change due to the amount of injection current and/or the temperature of the laser diode 105, which will also change the two or more frequencies that are part of the self-injection-locked light beam 110′. It will be recognized that the laser light reflected back from the partial reflector 125 will enter the laser diode 105 and pass through mirror 310B, where it interacts with the light generated by the semiconductor gain medium 305 to produce the self-injection-locked light beam 110′ that exhibits the at least two locked frequencies having a frequency difference lying in the terahertz range.

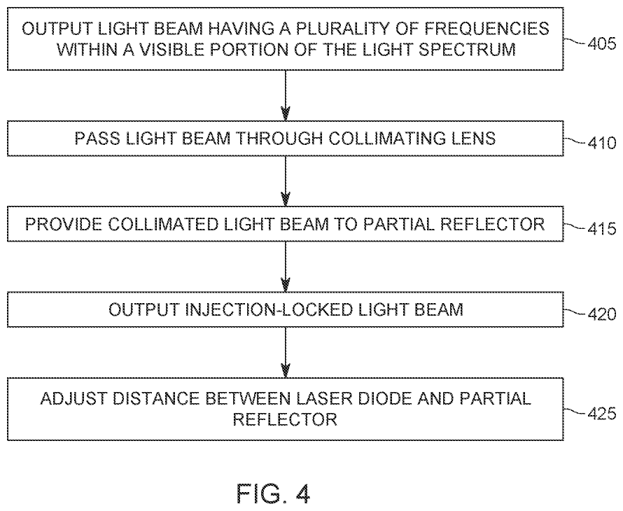

FIG. 4 is the flow diagram of method for tuning the at least two wavelengths of the light beam 110′ output by a laser according to embodiments. Initially, the laser diode 105 outputs a light beam 110 comprising a plurality of frequencies within a visible portion of the light spectrum (step 405). The light beam 110 passes through a collimating lens 115 to produce a collimated light beam 120 (step 410). The collimated light beam 120 is provided to a partial reflector 125 (step 415). A first portion 130 of the collimated laser 120 reflects back into the laser diode 105 and a second portion of the collimated laser 120 passes through the partial reflector 125 (the second portion 135 being the usable output light beam of the system). The laser diode 105 outputs, due to the mixing of the light beam 110 and the first portion of the collimated light beam 120, a self-injection-locked light beam 110′ comprising at least two frequencies in the visible portion of the light spectrum and having a frequency difference in a terahertz frequency range (step 420). A distance 145 between the laser diode 105 and the partial reflector 125 is adjusted to select the at least two frequencies of the self-injection-locked light beam 110′ (step 425).

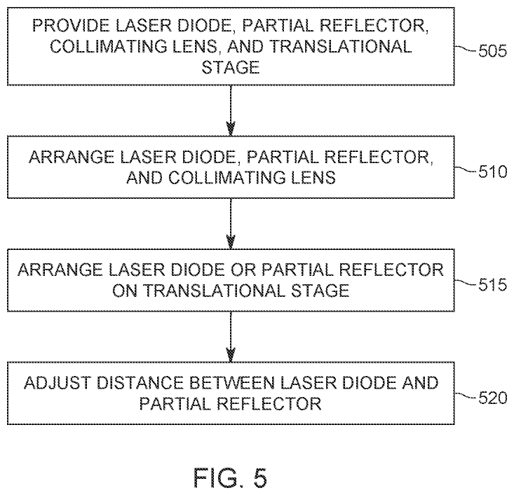

FIG. 5 is a flow diagram of a method of producing a tunable laser system according to embodiments. A laser diode 105, partial reflector 125, collimating lens 115, and translational stage 140A or 140B are provided (step 505). The laser diode 105 is configured to produce a light beam 110 having a plurality of frequencies in a visible portion of a light spectrum. The laser diode 105, partial reflector 125, and collimating lens 115 are arranged so that a laser 110 output from the laser diode 105 passes through the collimating lens 115 to the partial reflector 125 (step 510). The laser diode 105 or the partial reflector 125 is arranged on the translational stage 140A or 140B (step 515). The distance 145 between the laser diode 105 and partial reflector 125 is adjusted, by moving the translational stage 140A or 140B, so that a light beam reflected by the partial reflector into the laser diode 105 mixes with a light beam 110 produced by the laser diode 105 to produce a self-injection-locked light beam 110′ comprising at least two frequencies in the visible portion of the light spectrum and having a frequency difference in a terahertz frequency range (step 520). The at least two frequencies of the self-injection-locked light beam 110′ are based on the distance 145 between the laser diode 105 and the partial reflector 125.

As will be appreciated from the discussion above, the tunable laser system is able to output a self-injection-locked light beam having at least two wavelengths or frequencies with a terahertz frequency difference between them using a laser diode that lases in the visible light frequency range. Further, system uses a single laser diode operating in a self-locking manner, and thus does not involve the complications encountered in the prior art arrangements that employed a second laser to lock the first laser.

The disclosed embodiments provide systems and methods for tuning a laser to exhibit two wavelengths or frequencies such that the difference of which lie in a range of terahertz frequencies. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present exemplary embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

1. A tunable laser system for photonic generation of the terahertz frequencies, comprising:
a laser diode configured to produce a light beam having a plurality of frequencies in a visible portion of a light spectrum;
a collimating lens arranged in front of the laser diode and configured to produce a collimated light beam from the light beam produced by the laser diode;
a partial reflector arranged in a path of the collimated laser beam and configured to reflect a first portion of the collimated light beam and to pass a second portion of the collimated light beam as an output light beam, wherein the first portion of the collimated light beam enters the laser diode and mixes with the plurality of frequencies of the light beam produced by the laser diode so that the laser diode produces a self-injection-locked light beam comprising at least two frequencies that have a frequency difference in a terahertz frequency range; and
a translational stage configured to adjust a distance between the laser diode and the partial reflector, wherein the laser diode or the partial reflector is mounted on the translational stage, wherein the at least two frequencies of the self-injection-locked light beam are based on the distance between the laser diode and the partial reflector.

2. The tunable laser system of claim 1, wherein the laser diode, partial reflector, and collimating lens are arranged along a single optical axis.

3. The tunable laser system of claim 1, wherein the laser diode has an internal cavity length ranging from 300 to 1500 μm.

4. The tunable laser system of claim 3, wherein the laser diode is tunable based on injection current.

5. The tunable laser system of claim 3, wherein the laser diode is tunable based on a temperature of the laser diode.

6. The tunable laser system of claim 3, wherein the laser diode includes two mirrors, wherein a distance between the two mirrors of the laser diode changes based on temperature or injection current.

7. The tunable laser system of claim 1, wherein the laser diode comprises a III-nitride active region.

8. The tunable laser system of claim 7, wherein the III-nitride active region comprises InGaN/GaN multiple quantum well or InGaN/GaN quantum dot layers.

9. The tunable laser system of claim 1, wherein the translational stage is a manually-actuated translational stage.

10. The tunable laser system of claim 1, wherein the translational stage is a motorized translational stage.

11. The tunable laser system of claim 1, wherein the laser diode is a single laser diode that produces the portion of the light beam passing through the partial reflector having terahertz frequency difference that is the usable output power.

12. A method of using a tunable laser system, the method comprising:
outputting, from a laser diode, a light beam comprising a plurality of frequencies within a visible portion of a light spectrum;
passing the light beam through a collimating lens to produce a collimated light beam;
providing the collimated light beam to a partial reflector), wherein a first portion of the collimated light beam reflects back into the laser diode and a second portion of the collimated light beam passes through the partial reflector;
outputting, from the laser diode due to mixing of the light beam and the first portion of the collimated light beam, a self-injection-locked light beam comprising at least two frequencies in the visible portion of the light spectrum and having a frequency difference in a terahertz frequency range; and
adjusting a distance between the laser diode and the partial reflector to select the at least two frequencies of the self-injection-locked light beam.

13. The method of claim 12, wherein the partial reflector is mounted on a translational stage and the translational stage is moved to adjust the distance between the laser diode and the partial reflector.

14. The method of claim 12, wherein the laser and collimating lens are mounted on the translational stage and the translational stage is moved to adjust the distance between the laser diode and the partial reflector.

15. The method of claim 12, wherein the laser diode is a tunable laser diode, the method further comprising:
adjusting an operational parameter of the laser diode to adjust the wavelength produced by the laser diode.

16. The method of claim 15, wherein the operational parameter is an injection current to the laser diode or a temperature of the laser diode.

17. The method of claim 12, wherein the self-injection-locked light beam includes only two frequencies within the visible portion of the light spectrum and having a frequency difference in the terahertz frequency range.

18. The method of claim 12, wherein the laser diode is a single laser diode that self-injection locks by mixing the light beam and the first portion of the collimated light beam to produce the self-injection-locked light beam.

19. A method producing a dual wavelength tunable laser system, the method comprising:
providing a laser diode, partial reflector, collimating lens, and translational stage, wherein the laser diode is configured to produce a light beam having a plurality of frequencies in a visible portion of a light spectrum;
arranging the laser diode, partial reflector, and collimating lens so that a laser output from the laser diode passes through the collimating lens to the partial reflector; and
arranging the laser diode or the partial reflector on the translational stage; and
adjusting, by moving the translational stage, a distance between the laser diode and partial reflector so that a light beam reflected by the partial reflector into the laser diode mixes with a light beam produced by the laser diode to produce a self-injection-locked light beam comprising at least two frequencies in the visible portion of the light spectrum and having a frequency difference in a terahertz frequency range, wherein the at least two frequencies of the self-injection-locked light beam are based on the distance between the laser diode and the partial reflector.

20. The method of claim 19, wherein a cavity between the laser diode and the partial reflector is an open-air cavity.
